(19) United States
(12) Patent Application Publication
(10) Pub. No.: US 2026/0036657 A1
(43) Pub. Date: Feb. 5, 2026

(54) METHOD IN MAGNETIC RESONANCE IMAGING AND MAGNETIC RESONANCE IMAGING APPARATUS

(71) Applicant: CANON MEDICAL SYSTEMS CORPORATION, Otawara-shi (JP)

(72) Inventors: Yutaka MACHII, Otawara (JP); Naoyuki FURUDATE, Otawara (JP); Masaaki UMEDA, Sakura (JP)

(73) Assignee: CANON MEDICAL SYSTEMS CORPORATION, Otawara-shi (JP)

(21) Appl. No.: 19/274,735

(22) Filed: Jul. 21, 2025

(30) Foreign Application Priority Data
Aug. 5, 2024 (JP) 2024-129232

(51) Int. Cl. G01R 33/36; G01R 33/3815; G01R 33/385; G01R 33/48

(52) U.S. Cl. CPC G01R 33/3607; G01R 33/3815; G01R 33/385; G01R 33/4818

(57) ABSTRACT

A method in magnetic resonance imaging according to an exemplary embodiment includes acquiring a first temperature variation amount as a variation amount of a temperature of a gradient coil unit which includes a gradient coil corresponding to an X-axis; a gradient coil corresponding to a Y-axis; and a gradient coil corresponding to a Z-axis; and a first frequency variation amount as a shift amount of a center frequency at which nuclear spin of a subject causes magnetic resonance, the first temperature variation amount and the first frequency variation amount being caused by execution of a first sequence based on a first setting in which a readout gradient magnetic field is applied in a direction of the X-axis by the gradient coil unit; acquiring a second temperature variation amount as the variation amount of the temperature of the gradient coil unit and a second frequency variation amount as the shift amount of the center frequency, the second temperature variation amount and the second frequency variation amount being caused by execution of the first sequence based on a second setting in which the readout gradient magnetic field is applied in a direction of the Y-axis by the gradient coil unit; acquiring a third temperature variation amount as the variation amount of the temperature of the gradient coil unit and a third frequency variation amount as a shift amount of the center frequency, the third temperature variation amount and the third frequency variation amount being caused by execution of the first sequence based on a third setting in which the readout gradient magnetic field is applied in a direction of the Z-axis by the gradient coil unit; and acquiring a fourth temperature variation amount as the variation amount of the temperature of the gradient coil unit caused by execution of a second sequence to be executed after the first sequence, and calculating a value corresponding to the shift amount of the center frequency in the second sequence, based on the first temperature variation amount, the first frequency variation amount, the second temperature variation amount, the second frequency variation amount, the third temperature variation amount, the third frequency variation amount, the fourth temperature variation amount, and a weighting value corresponding to a gradient magnetic field to be applied in the second sequence.

### CROSS-REFERENCE TO RELATED APPLICATIONS

This application is based upon and claims the benefit of priority from Japanese Patent Application No. 2024-129232, filed Aug. 5, 2024, the entire contents of which are incorporated herein by reference.

### FIELD

Embodiments described herein relate generally to a method in magnetic resonance imaging and a magnetic resonance imaging apparatus.

### BACKGROUND

A magnetic resonance imaging (MRI) apparatus is an imaging apparatus that excites nuclear spin of a subject placed in a static magnetic field with a radio frequency (RF) pulse of a Larmor frequency, executes scanning to collect magnetic resonance (MR) signals generated from the subject due to excitation, and generates an MR image based on the MR signals collected by scanning. By application of not only a uniform static magnetic field, but also a gradient magnetic field that spatially changes, spatial positional information on the MR signals is added.

When a gradient coil is supplied with a pulse current from a gradient magnetic field power supply during scanning, the gradient coil generates a gradient magnetic field, and as the pulse current is repeatedly supplied, the gradient coil generates heat, which changes the temperature of a gradient coil unit. Due to a temperature change of the gradient coil unit, a magnetic field within a bore is changed, and a center frequency at which nuclear spin of the subject causes magnetic resonance is also changed.

The center frequency of an RF pulse is set based on the Larmor frequency prior to scanning. When the center frequency at which nuclear spin of the subject causes magnetic resonance is changed during scanning, for example, a fat-suppression prepulse may not effectively function, which results in degradation of the image quality of an MR image. To prevent such degradation of the image quality of an MR image, there is a method for correcting the center frequency of the RF pulse based on a relationship between a temperature change of a gradient coil unit and a shift amount of the center frequency at which nuclear spin of a subject causes magnetic resonance.

### BRIEF DESCRIPTION OF THE DRAWINGS

FIG. 1 is a block diagram illustrating an overall configuration example of a magnetic resonance imaging (MRI) apparatus according to an exemplary embodiment;

FIG. 2 is a block diagram illustrating a configuration example of processing circuitry of the MRI apparatus according to the exemplary embodiment;

FIG. 3 is a flowchart illustrating an example of an operation for executing scanning by a first sequence;

FIG. 4 is a schematic sequence diagram illustrating first and second sequences;

FIGS. 5A to 5C are graphs each illustrating an example of a temporal change of a temperature at predetermined positions on a gradient coil when scanning is executed by the first sequence based on first, second, and third settings;

FIG. 6 is a flowchart illustrating an example of operation for correcting a shift amount of a center frequency caused by execution of scanning by the second sequence;

FIGS. 7A to 7C are graphs each illustrating an example of a temporal change of a calculated value and a measured value of the shift amount of the center frequency when a readout gradient magnetic field is applied in an X-axis direction, a Y-axis direction, or a Z-axis direction during a main scan according to a comparative example;

FIGS. 8A to 8C are graphs each illustrating an example of a temporal change of a calculated value and a measured value of the shift amount of the center frequency when the readout gradient magnetic field is applied in the X-axis direction, the Y-axis direction, or the Z-axis direction during the main scan according to the exemplary embodiment;

FIGS. 9A to 9C each illustrate image quality of a signal-averaged magnetic resonance (MR) image according to the comparative example; and

FIGS. 10A to 10C each illustrate image quality of a signal-averaged MR image according to the exemplary embodiment.

### DETAILED DESCRIPTION

A method in magnetic resonance imaging according to an exemplary embodiment includes acquiring a first temperature variation amount as a variation amount of a temperature of a gradient coil unit which includes a gradient coil corresponding to an X-axis; a gradient coil corresponding to a Y-axis; and a gradient coil corresponding to a Z-axis; and a first frequency variation amount as a shift amount of a center frequency at which nuclear spin of a subject causes magnetic resonance, the first temperature variation amount and the first frequency variation amount being caused by execution of a first sequence based on a first setting in which a readout gradient magnetic field is applied in a direction of the X-axis by the gradient coil unit; acquiring a second temperature variation amount as the variation amount of the temperature of the gradient coil unit and a second frequency variation amount as the shift amount of the center frequency, the second temperature variation amount and the second frequency variation amount being caused by execution of the first sequence based on a second setting in which the readout gradient magnetic field is applied in a direction of the Y-axis by the gradient coil unit; acquiring a third temperature variation amount as the variation amount of the temperature of the gradient coil unit and a third frequency variation amount as a shift amount of the center frequency, the third temperature variation amount and the third frequency variation amount being caused by execution of the first sequence based on a third setting in which the readout gradient magnetic field is applied in a direction of the Z-axis by the gradient coil unit; and acquiring a fourth temperature variation amount as the variation amount of the temperature of the gradient coil unit caused by execution of a second sequence to be executed after the first sequence, and calculating a value corresponding to the shift amount of the center frequency in the second sequence, based on the first temperature variation amount, the first frequency variation amount, the second temperature variation amount, the second frequency variation amount, the third temperature variation amount, the third frequency variation amount, the fourth temperature variation amount, and a weighting value corresponding to a gradient magnetic field to be applied in the second sequence.

A method in magnetic resonance imaging according to an exemplary embodiment may include acquiring a first temperature variation amount as a variation amount of a temperature of a gradient coil unit which includes a gradient coil corresponding to a first axis and a gradient coil corresponding to a second axis, and acquiring a first frequency variation amount as a shift amount of a center frequency at which nuclear spin of a subject causes magnetic resonance, the first temperature variation amount and the first frequency variation amount being caused by execution of a first sequence based on a first setting in which a readout gradient magnetic field is applied in a direction of the first axis by the gradient coil unit; acquiring a second temperature variation amount as the variation amount of the temperature of the gradient coil unit and a second frequency variation amount as the shift amount of the center frequency, the second temperature variation amount and the second frequency variation amount being caused by execution of the first sequence based on a second setting in which the readout gradient magnetic field is applied in a direction of the second axis by the gradient coil unit; acquiring a third temperature variation amount as the variation amount of the temperature of the gradient coil unit caused by execution of a second sequence to be executed after the first sequence; and calculating a value corresponding to the shift amount of the center frequency in the second sequence, based on the first temperature variation amount, the first frequency variation amount, the second temperature variation amount, the second frequency variation amount, the third temperature variation amount and a weighting value corresponding to a gradient magnetic field to be applied in the second sequence.

Various Embodiments will be described hereinafter with reference to the accompanying drawings.

In the drawings, the same elements are denoted by the same reference symbols, and duplicate descriptions are omitted.

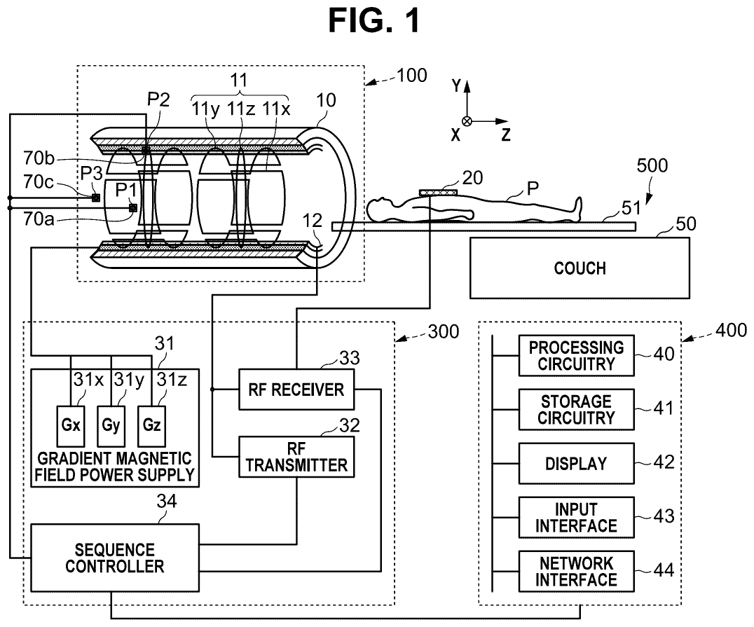

FIG. 1 is a block diagram illustrating an overall configuration example of an MRI apparatus 1 according to an exemplary embodiment. The MRI apparatus 1 includes a gantry 100, a control cabinet 300, an image processing apparatus 400, and a couch 500. Assume that, as illustrated in FIG. 1, a left-right direction of a subject P located on the couch 500 is referred to as an X-axis direction, a back-front direction (body thickness direction) of the subject P is referred to as a Y-axis direction, and a head-foot direction of the subject P is referred to as a Z-axis direction. An X-axis, a Y-axis, and a Z-axis are orthogonal to each other.

The gantry 100 includes a static field magnet 10, a gradient coil unit 11, and a whole body (WB) coil 12. The static field magnet 10, the gradient coil unit 11, and the WB coil 12 are accommodated in a cylindrical housing.

The static field magnet 10 has a substantially cylindrical shape and generates a static magnetic field within a bore in which a patient as the subject P is located. The term “bore” refers to an examination space within a cylinder of the static field magnet 10. The static field magnet 10 incorporates a superconducting coil, and the superconducting coil is cooled to an extremely low temperature by liquid helium. The static field magnet 10 applies a current supplied from a power supply (not illustrated) for a static magnetic field in an excitation mode to the superconducting coil, thereby generating the static magnetic field. After that, the static field magnet 10 transitions to a persistent current mode, so that the power supply for the static magnetic field is disconnected. Once the static field magnet 10 transitions to the persistent current mode, the static field magnet 10 continuously generates a large static magnetic field for a long period of time, for example, over one year. The static field magnet 10 may be formed of a permanent magnet.

The gradient coil unit 11 has a substantially cylindrical shape and is fixed to the inside of the static field magnet 10 in a radial direction of the cylindrical shape. The gradient coil unit 11 receives a current supplied from a gradient magnetic field power supply unit 31 and generates a gradient magnetic field. Specifically, the gradient coil unit 11 includes a gradient coil 11X corresponding to the X-axis, a gradient coil 11Y corresponding to the Y-axis, and a gradient coil 11Z corresponding to the Z-axis. The triaxial gradient coils 11X, 11Y, and 11Z generate gradient magnetic fields by changing magnetic field intensities along the X-axis, the Y-axis, and the Z-axis, which are orthogonal to each other.

The MRI apparatus 1 includes temperature sensors 70a, 70b, and 70c. The temperature sensors 70a, 70b, and 70c each include a temperature detector such as an infrared radiation thermometer, a thermistor, or a thermocouple thermometer. The temperature sensors 70a, 70b, and 70c are located at predetermined positions P1, P2, and P3, respectively, and detect the temperature of the gradient coil unit 11. The temperature sensors 70a, 70b, and 70c output the detected temperature to a sequence controller 34.

The number of temperature sensors is not limited to three as exemplified in FIG. 1. One or more temperature sensors may be used. In other words, one or more predetermined positions may be set as positions where the temperature is detected. The position of each temperature sensor is not limited to the position exemplified in FIG. 1 as long as each temperature sensor is located at a predetermined position where the temperature of the gradient coil unit 11 can be detected. Each temperature sensor may be located at another position within the gradient coil unit 11. For example, each temperature sensor may be located on a shim tray in an actively shielded gradient coil (ASGC) including main coils for generating gradient magnetic fields of the X-axis, the Y-axis, and the Z-axis, the shim tray capable of accommodating a plurality of magnetic shims, and a shield coil for suppressing a leakage magnetic field. Each temperature sensor may be located between the gradient coil unit 11 and the static field magnet 10.

The temperature sensors 70a, 70b, and 70c may be desirably located at predetermined positions where a temperature change at each axis of the gradient coils 11X, 11Y, and 11Z corresponding to the X-axis, the Y-axis, and the Z-axis, respectively, can be effectively detected. The plurality of predetermined positions at which the temperature sensors 70a, 70b, and 70c are located, respectively, may correspond to three spatial positions including the position P1 that is in proximity to the gradient coil 11X corresponding to the X-axis, the position P2 that is in proximity to the gradient coil 11Y corresponding to the Y-axis, and the position P3 that is neither in proximity to the gradient coil 11X corresponding to the X-axis nor in proximity to the gradient coil 11Y corresponding to the Y-axis.

The WB coil 12 has a substantially cylindrical shape and is fixed to the inside of the gradient coil unit 11 in such a manner that the WB coil 12 surrounds the subject P. The WB coil 12 transmits a radio frequency (RF) pulse generated by an RF transmitter 32 to the subject P, and receives a magnetic resonance (MR) signal emitted from the subject P upon excitation of a hydrogen nucleus.

The MRI apparatus 1 may include a local coil 20 in addition to the WB coil 12. The local coil 20 is located in proximity to the body surface of the subject P. Examples of the type of the local coil 20 include a head coil, a chest coil, an abdominal coil, a spine coil, and a knee coil. The local coil 20 includes a receive-only coil, a transmit-only coil, and a transmit/receive coil that performs both transmission and reception. The local coil 20 is, for example, detachably mounted on a couchtop 51 via a cable.

The control cabinet 300 includes the gradient magnetic field power supply unit 31, the RF transmitter 32, an RF receiver 33, and the sequence controller 34. The gradient magnetic field power supply unit 31 supplies a current to the gradient coil unit 11 under control of the sequence controller 34. Specifically, the gradient magnetic field power supply unit 31 includes triaxial gradient magnetic field power supplies 31X, 31Y, and 31Z corresponding to the X-axis, the Y-axis, and the Z-axis, respectively. The triaxial gradient magnetic field power supplies 31X, 31Y, and 31Z supply currents to generate gradient magnetic fields at the axes of the triaxial gradient coils 11X, 11Y, and 11Z, respectively.

The RF transmitter 32 generates an RF pulse under the control of the sequence controller 34. The RF transmitter 32 can generate the RF pulse, a center frequency of which is corrected. The generated RF pulse is transmitted to the WB coil 12 or the local coil 20 and is applied to the subject P. The RF receiver 33 detects an MR signal received by the WB coil 12 or the local coil 20, performs an analog-to-digital (AD) conversion of the detected MR signal, and outputs the converted MR signal to the sequence controller 34. The digitalized MR signal is referred to as raw data.

The sequence controller 34 executes scanning on the subject P by driving the gradient magnetic field power supply unit 31, the RF transmitter 32, and the RF receiver 33 under control of the image processing apparatus 400. The sequence controller 34 receives raw data from the RF receiver 33 by scanning, and transmits the received raw data to the image processing apparatus 400. Further, the sequence controller 34 receives information about the temperature of the gradient coil unit 11 from the temperature sensors 70a, 70b, and 70c, and transmits the received information to the image processing apparatus 400.

The sequence controller 34 includes processing circuitry (not illustrated). The processing circuitry is composed of hardware such as a processor that executes a predetermined program, a Field-Programmable Gate Array (FPGA), and an Application-Specific Integrated Circuit (ASIC).

The couch 500 includes a couch body 50 and the couchtop 51. The couch body 50 is configured to allow the couchtop 51 to move in a vertical direction and a horizontal direction. The couch body 50 moves the subject P who is placed on the couchtop 51 to a predetermined height, and moves the couchtop 51 in the horizontal direction to thereby locate the subject P within the bore.

The image processing apparatus 400 includes processing circuitry 40, storage circuitry 41, a display 42, and an input interface 43. The image processing apparatus 400 may include a network interface 44. The image processing apparatus 400 controls the entire MRI apparatus 1.

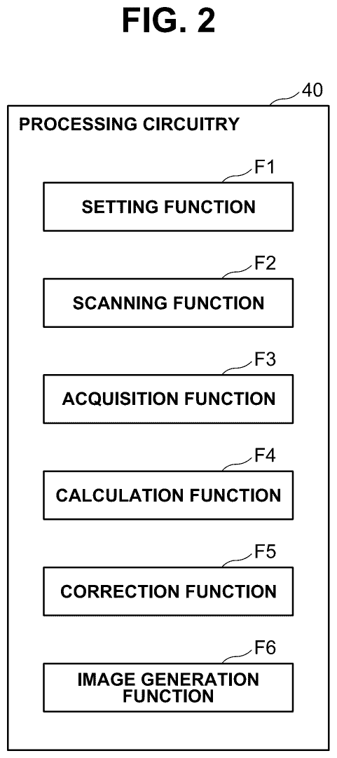

The processing circuitry 40 is circuitry including, for example, a central processing unit (CPU) or a dedicated or general-purpose processor. FIG. 2 is a block diagram illustrating a configuration example of the processing circuitry 40 of the MRI apparatus 1 according to the exemplary embodiment. The processor performs software processing by executing various programs that are stored in the storage circuitry 41 or are directly built in the processing circuitry 40, thereby implementing various functions including a setting function F1, a scanning function F2, an acquisition function F3, a calculation function F4, a correction function F5, and an image generation function F6.

The storage circuitry 41 includes, for example, a storage medium including a semiconductor memory element such as a random access memory (RAM) or a flash memory, or an external storage device such as a hard disk or an optical disk. The storage circuitry 41 may be a portable medium such as a Universal Serial Bus (USB) memory or a Digital Video Disk (DVD). The storage circuitry 41 stores various kinds of information and data, and also stores various programs to be executed by the processor of the processing circuitry 40.

The display 42 includes a display device such as a liquid-crystal display or an organic light-emitting diode (OLED) display. The display 42 displays various kinds of information under control of the processing circuitry 40. The display 42 may be a graphics user interface (GUI) that functions as a display device as well as an input device.

The input interface 43 includes an input device and input circuitry. The input device is implemented using a trackball, a switch, a mouse, a keyboard, a touch pad, a touch screen, a contactless input device using an optical sensor, an audio input device, or the like. When the input device is operated by a user, the input circuitry generates a signal in accordance with the operation and outputs the generated signal to the processing circuitry 40.

The network interface 44 communicates with various apparatuses connected to a network by wired communication or wireless communication to exchange various kinds of information and data.

Using the above-described components, the image processing apparatus 400 controls the overall operation of the MRI apparatus 1. Specifically, the processing circuitry 40 receives instructions regarding imaging conditions and other various kinds of information through an operation by the user such as a technician via the input interface 43. Further, the processing circuitry 40 causes the sequence controller 34 to execute scanning based on input imaging conditions, and reconstructs an MR image based on raw data received from the sequence controller 34. The reconstructed MR image is displayed on the display 42 and is stored in the storage circuitry 41.

When the gradient coils 11X, 11Y, and 11Z are repeatedly supplied with pulse currents from the gradient magnetic field power supplies 31X, 31Y, and 31Z during scanning, the gradient coils 11X, 11Y, and 11Z consume energy and generate heat, which changes the temperature of the gradient coil unit 11. With a temperature change of the gradient coil unit 11, a magnetic field within the bore is changed, and a center frequency at which nuclear spin (e.g., hydrogen atoms) of the subject P causes magnetic resonance is changed.

The center frequency of an RF pulse is set based on a Larmor frequency before scanning. However, if the center frequency at which nuclear spin of the subject P causes magnetic resonance is changed (or shifted) during a main scan, image quality of an MR image may be degraded. To prevent degradation of the image quality of the MR image, in a method according to a comparative example, a prescan is executed based only on a first setting in which a readout gradient magnetic field is applied by the gradient coil 11X corresponding to the X-axis, and a variation amount of the temperature of the gradient coil unit 11 and a shift amount of the center frequency are detected. Then, the center frequency of the RF pulse is corrected based on a relationship between the temperature change of the gradient coil unit 11 and the shift amount of the center frequency, which are detected during the prescan. In the method according to the comparative example, since the prescan is executed based only on the first setting, it is sometimes difficult to accurately correct the shift amount of the center frequency that changes during the main scan.

The term “prescan” used herein refers to scanning for collecting MR signals for adjusting a center frequency, active shimming, a transmission gain, a reception gain, and the like. The prescan is also referred to as scanning by a first sequence. The term “main scan” refers to scanning for collecting MR signals for generating an MR image to be used for diagnosis, testing, positioning, and the like. The main scan is also referred to as scanning by a second sequence. After one prescan, one main scan may be executed, or a plurality of main scans may be executed.

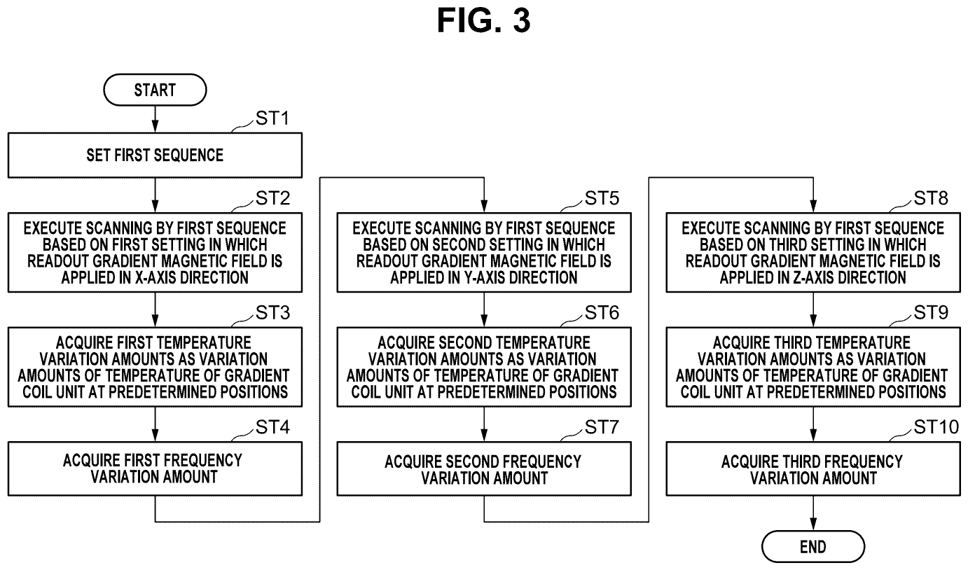

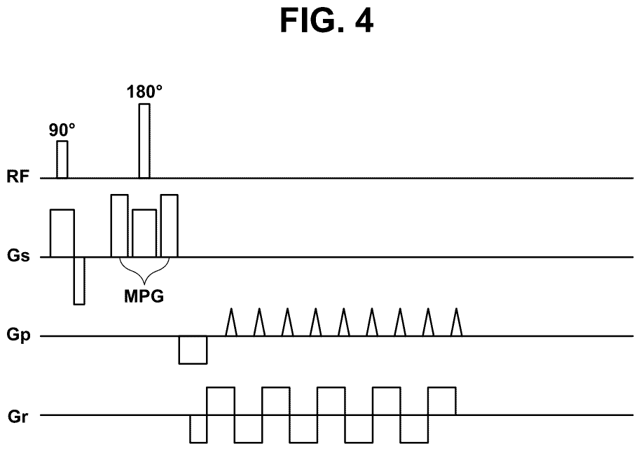

In the exemplary embodiment, the prescan is performed based on three settings, i.e., the setting in which a readout gradient magnetic field Gr (see FIG. 4) is applied by the gradient coil 11X corresponding to the X-axis, the setting in which the readout gradient magnetic field Gr is applied by the gradient coil 11Y corresponding to the Y-axis, and the setting in which the readout gradient magnetic field Gr is applied by the gradient coil 11Z corresponding to the Z-axis, so that a variation amount of the temperature of the gradient coil unit 11 and a shift amount of the center frequency at which nuclear spin of the subject P causes magnetic resonance can be detected. For example, a temporal change of the temperature of the gradient coil unit 11 and a temporal change of the center frequency at which nuclear spin of the subject P causes magnetic resonance may be observed, and the variation amount of the temperature of the gradient coil unit 11 and the shift amount of the center frequency may be calculated. Execution of a prescan according to the exemplary embodiment, or scanning by the first sequence, will be described with reference to a flowchart of FIG. 3. Hereinafter, assume a case where the temperature sensors 70a, 70b, and 70c are located at three positions (i.e., the predetermined positions P1, P2, and P3), respectively.

In step ST1, the setting function F1 sets the first sequence. For example, the first sequence is set based on the second sequence to be set in accordance with an examination content. The first sequence may be set by reading out imaging conditions preliminarily stored in the storage circuitry 41.

FIG. 4 illustrates a Spin Echo-Echo Planar Imaging (SE-EPI) method as a schematic sequence diagram of the first sequence. However, the first sequence is not limited to the SE-EPI method. Any known sequence such as a Fast Spin Echo (FSE) method can be used. A sequence desirable as the first sequence will be described in detail below.

In the SE-EPI method, 90° and 180° excitation pulses that generate a spin echo signal are applied as RF pulses along with a slice selection gradient magnetic field Gs for slice selection of a scanning region. After application of the 90° and 180° excitation pulses, the readout gradient magnetic field Gr is applied that rapidly switches in a kx-direction in a k-space between positive and negative values to quickly collect multiple echoes. A blip pulse that moves the readout gradient magnetic field Gr in a ky-direction along with the rapid switching of the readout gradient magnetic field Gr is applied as a phase encoding gradient magnetic field Gp. A Motion Probing Gradient (MPG) pulse for acquiring a diffusion-weighted image may be further applied to the slice selection gradient magnetic field Gs, the phase encoding gradient magnetic field Gp, or the readout gradient magnetic field Gr.

In step ST2, the scanning function F2 executes scanning of the first sequence based on a first setting in which the readout gradient magnetic field Gr is applied in the X-axis direction by the gradient coil unit 11.

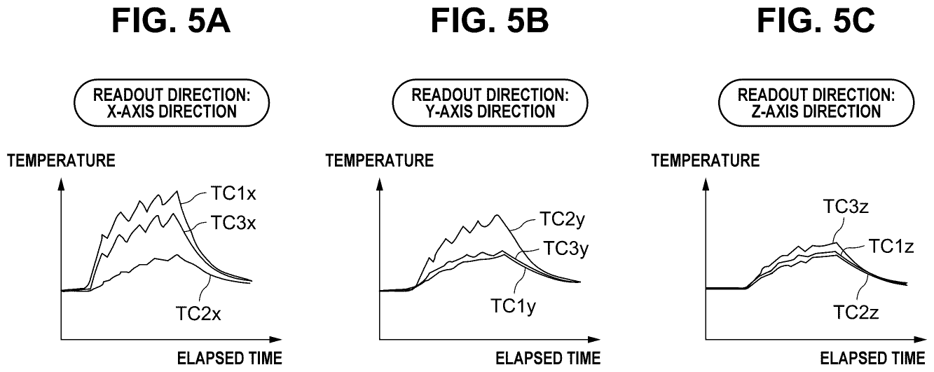

In step ST3, the acquisition function F3 acquires first temperature variation amounts TC1x, TC2x, and TC3x as variation amounts of the temperature of the gradient coil unit 11 upon execution of scanning by the first sequence based on the first setting. The first temperature variation amounts TC1x, TC2x, and TC3x are the variation amounts of the temperature that are detected by the temperature sensors 70a, 70b, and 70c, respectively, and are acquired at the predetermined positions P1, P2, and P3, respectively. One or more first temperature variation amounts are acquired depending on the number of predetermined positions. FIG. 5A illustrates an example of a temporal change of each of the first temperature variation amounts TC1x, TC2x, and TC3x.

In step ST4, the acquisition function F3 acquires a first frequency variation amount CFx as a shift amount of the center frequency at which nuclear spin of the subject P causes magnetic resonance upon execution of scanning by the first sequence based on the first setting.

In step ST5, the scanning function F2 executes scanning by the first sequence based on a second setting in which the readout gradient magnetic field Gr is applied in the Y-axis direction by the gradient coil unit 11.

In step ST6, the acquisition function F3 acquires second temperature variation amounts TC1y, TC2y, and TC3y as variation amounts of the temperature of the gradient coil unit 11 upon execution of scanning by the first sequence based on the second setting. The second temperature variation amounts TC1y, TC2y, and TC3y are variation amounts of temperature that are detected by the temperature sensors 70a, 70b, and 70c, respectively, and are acquired at the predetermined positions P1, P2, and P3, respectively. One or more second temperature variation amounts are acquired depending on the number of predetermined positions. FIG. 5B illustrates an example of a temporal change of each of the second temperature variation amounts TC1y, TC2y, and TC3y.

In step ST7, the acquisition function F3 acquires a second frequency variation amount CFy as a shift amount of the center frequency at which nuclear spin of the subject P causes magnetic resonance upon execution of scanning by the first sequence based on the second setting.

In step ST8, the scanning function F2 executes scanning by the first sequence based on a third setting in which the readout gradient magnetic field Gr is applied in the Z-axis direction by the gradient coil unit 11.

In step ST9, the acquisition function F3 acquires third temperature variation amounts TC1z, TC2z, and TC3z as variation amounts of the temperature of the gradient coil unit 11 upon execution of scanning by the first sequence based on the third setting. The third temperature variation amounts TC1z, TC2z, and TC3z are variation amounts of temperature that are detected by the temperature sensors 70a, 70b, and 70c, respectively, and are acquired at the predetermined positions P1, P2, and P3, respectively. One or more third temperature variation amounts are acquired depending on the number of predetermined positions. FIG. 5C illustrates an example of a temperature change of each of the third temperature variation amounts TC1z, TC2z, and TC3z.

In step ST10, the acquisition function F3 acquires a third frequency variation amount CFz as a shift amount of the center frequency at which nuclear spin of the subject P causes magnetic resonance upon execution of scanning by the first sequence based on the third setting.

Scanning based on the first setting (steps ST2 to ST4), scanning based on the second setting (steps ST5 to ST7), and scanning based on the third setting (steps ST8 to ST10) may be executed in any order.

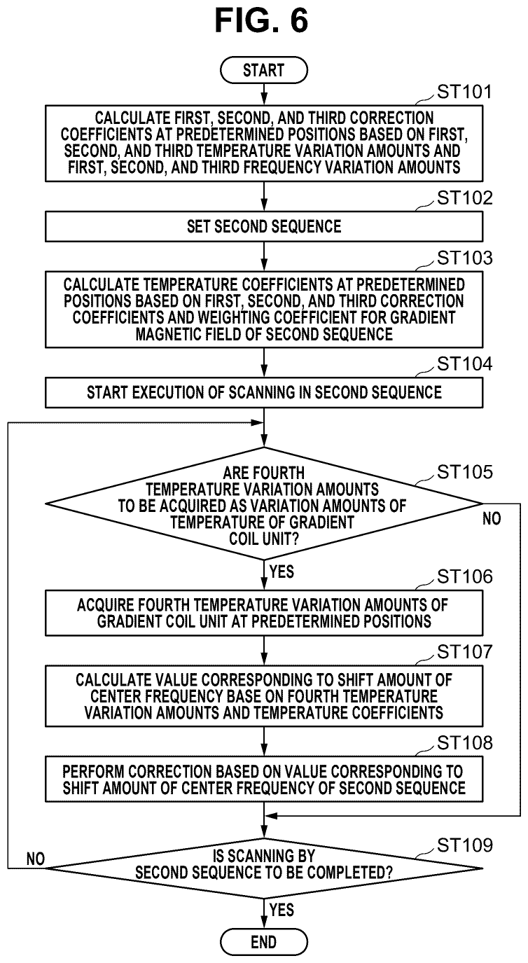

Next, a correction of a shift amount of the center frequency at which nuclear spin of the subject P causes magnetic resonance and execution of a main scan according to the exemplary embodiment, i.e., scanning by the second sequence, will be described with reference to a flowchart of FIG. 6.

In step ST101, the calculation function F4 calculates first, second, and third correction coefficients at predetermined positions as represented by Formulas (1) to (3), respectively, based on the first temperature variation amounts, the first frequency variation amount, the second temperature variation amounts, the second frequency variation amount, the third temperature variation amounts, and the third frequency variation amount, which are acquired in steps ST1 to ST10.

$$( OLP 1 x , OLP 2 x , OLP 3 x ) = ( TC 1 x / CFx , TC 2 x / CFx , TC 3 x / CFx ) \qquad Formula ( 1 )$$

$$( OLP 1 y , OLP 2 y , OLP 3 y ) = ( TC 1 y / CFy , TC 2 y / CFy , TC 3 y / CFy ) \qquad Formula ( 2 )$$

$$( OLP 1 z , OLP 2 z , OLP 3 z ) = ( TC 1 z / CFz , TC 2 z / CFz , TC 3 z / CFz ) \qquad Formula ( 3 )$$

First correction coefficients OLP1x, OLP2x, and OLP3x are ratios between the first frequency variation amount CFx and the first temperature variation amounts TC1x, TC2x, and TC3x at the predetermined positions P1, P2, and P3, respectively. Second correction coefficients OLP1y, OLP2y, and OLP3y are ratios between the second frequency variation amount CFy and the second temperature variation amounts TC1y, TC2y, and TC3y at the predetermined positions P1, P2, and P3, respectively. Third correction coefficients OLP1z, OLP2z, and OLP3z are ratios between the third frequency variation amount CFz and the third temperature variation amounts TC1z, TC2z, and TC3z at the predetermined positions P1, P2, and P3, respectively.

In step ST102, the setting function F1 sets the second sequence. For example, the second sequence may be set by a user input via the input interface 43, by reading out of imaging conditions preliminarily stored in the storage circuitry 41, or by a combination thereof. FIG. 4 is also a schematic sequence diagram of the second sequence. The second sequence is set depending on the type of pulse sequence corresponding to an examination content or imaging conditions. A known sequence such as the SE-EPI method or the FSE method can be used as the pulse sequence of the second sequence.

The imaging conditions include an orientation of an anatomical section such as an axial section, a coronal section, a sagittal section, or an oblique section, a field of view (FOV), a repetition time (TR), an echo time (TE), a slice thickness, the number of pieces of data on a frequency direction and a phase direction, a reception band width, and an addition count. The field of view indicates a two-dimensional or three-dimensional region to be imaged as an MR image.

Since the slice selection gradient magnetic field Gs, the phase encoding gradient magnetic field Gp, and the readout gradient magnetic field Gr independently have isotropy, they are decomposed and combined depending on the orientation of a section to be scanned, and are applied by the gradient coil 11X corresponding to the X-axis, the gradient coil 11Y corresponding to the Y-axis, and the gradient coil 11Z corresponding to the Z-axis.

In step ST103, the calculation function F4 calculates temperature coefficients based on the first correction coefficients OLP1x, OLP2x, and OLP3x, the second correction coefficients OLP1y, OLP2y, and OLP3y, the third correction coefficients OLP1z, OLP2z, and OLP3z, and a weighting coefficient regarding a gradient magnetic field of the second sequence. The temperature coefficients are respective coefficients at the predetermined positions P1, P2, and P3, and are used to correct the shift amount of the center frequency at which nuclear spin of the subject P causes magnetic resonance of the second sequence.

First, second, and third weighting coefficients regarding the gradient magnetic field applied in the second sequence are ratios between energy Egt to be consumed by the gradient coil 11X corresponding to the X-axis, the gradient coil 11Y corresponding to the Y-axis, and the gradient coil 11Z corresponding to the Z-axis upon execution of scanning by the second sequence and energies Egx, Egy, and Egz to be consumed by the gradient coil 11X corresponding to the X-axis, the gradient coil 11Y corresponding to the Y-axis, and the gradient coil 11Z corresponding to the Z-axis, respectively. The energies Egx, Egy, and Egz to be consumed by the gradient coil 11X corresponding to the X-axis, the gradient coil 11Y corresponding to the Y-axis, and the gradient coil 11Z corresponding to the Z-axis, respectively, are dependent on the current applied by the gradient coil depending on a waveform of the gradient magnetic field set in the second sequence.

In this case, as represented by Formulas (4) to (6), the calculation function F4 calculates a plurality of temperature coefficients OLP1, OLP2, and OLP3 at the predetermined positions P1, P2, and P3, respectively, by multiplying a first weighting coefficient Egx/Egt, a second weighting coefficient Egy/Egt, and a third weighting coefficient Egz/Egt by the first correction coefficients OLP1x, OLP2x, and OLP3x, the second correction coefficients OLP1y, OLP2y, and OLP3y, and the third correction coefficients OLP1z, OLP2z, and OLP3z, respectively.

$$OLP 1 = OLP 1 x * Egx / Egt + OLP 1 y * Egy / Egt + OLP 1 z * Egz / Egt \qquad Formula ( 4 )$$

$$OLP 2 = OLP 2 x * Egx / Egt + OLP 2 y * Egy / Egt + OLP 2 z * Egz / Egt \qquad Formula ( 5 )$$

$$OLP 3 = OLP 3 x * Egx / Egt + OLP 3 y * Egy / Egt + OLP 3 z * Egz / Egt \qquad Formula ( 6 )$$

The number of predetermined positions where the temperature of the gradient coil unit 11 is detected may be one. In a case where one predetermined position (e.g., the position P1) is set, one first temperature variation amount OLP1x, one second temperature variation amount OLP1y, and one third temperature variation amount OLP1z are acquired. In this case, the calculation function F4 calculates one temperature coefficient OLP1 at one predetermined position P1 of the gradient coil unit 11.

In step ST104, the scanning function F2 executes scanning by the second sequence.

In step ST105, the acquisition function F3 determines whether to acquire fourth temperature variation amounts TC1, TC2, and TC3 that are variation amounts of the temperature of the gradient coil unit 11 caused by execution of scanning by the second sequence. If the fourth temperature variation amounts TC1, TC2, and TC3 are not to be acquired (NO in step ST105), the processing proceeds to step ST109. If the fourth temperature variation amounts TC1, TC2, and TC3 are to be acquired (YES in step ST105), the processing proceeds to step ST106.

In step ST106, the acquisition function F3 acquires the fourth temperature variation amounts TC1, TC2, and TC3 as variation amounts of the temperature of the gradient coil unit 11 upon execution of scanning by the second sequence at the predetermined positions P1, P2, and P3. One or more fourth temperature variation amounts are acquired depending on the number of predetermined positions. Each of the fourth temperature variation amounts TC1, TC2, and TC3 can be acquired at a predetermined timing. The acquisition function F3 may acquire the fourth temperature variation amounts TC1, TC2, and TC3 at at least one of timings of between addition counts, between multi-slices, and between dynamic scans during the execution of scanning by the second sequence.

In step ST107, the calculation function F4 calculates a value CFcorr corresponding to a shift amount of the center frequency at which nuclear spin of the subject P causes magnetic resonance of the second sequence based on the fourth temperature variation amounts TC1, TC2, and TC3 at the predetermined positions P1, P2, and P3, respectively, and the temperature coefficients OLP1, OLP2, and OLP3 at the predetermined positions P1, P2, and P3, respectively. As represented by Formula (7), the value CFcorr is calculated by averaging correction values OLP1*TC1, OLP2*TC2, and OLP3*TC3, which are obtained by multiplying the fourth temperature variation amounts by the temperature coefficients at the predetermined positions P1, P2, and P3, respectively, with the number of the predetermined positions. If one predetermined position P1 is set, OLP1*TC1 is calculated as the value CFcorr corresponding to the shift amount.

$$CFcorr = ( OLP 1 * TC 1 + OLP 2 * TC 2 + OLP 3 * TC 3 ) / 3 \qquad Formula ( 7 )$$

In step ST108, the correction function F5 performs a correction based on the value CFcorr corresponding to the shift amount of the center frequency of the second sequence. The correction function F5 sets the center frequency of the RF pulse of the second sequence during execution of scanning by the second sequence based on the value CFcorr.

As described above, the center frequency of the RF pulse in the second sequence is corrected based on the values obtained by weighting the ratio between the first frequency variation amount CFx and the first temperature variation amounts TC1x, TC2x, and TC3x, the ratio between the second frequency variation amount CFy and the second temperature variation amounts TC1y, TC2y, and TC3y, and the ratio between the third frequency variation amount CFz and the third temperature variation amounts TC1z, TC2z, and TC3z by weighting coefficients.

In this case, the center frequency of the RF pulse can be corrected for each RF pulse or at a predetermined timing. The correction function F5 may set the center frequency of the RF pulse in the second sequence at at least one of timings of between addition counts, between multi-slices, and between dynamic scans during the execution of scanning by the second sequence. The RF pulse to be corrected include RF pulses that affect contrast enhancement of an MR image, such as an excitation pulse for collecting MR signals, a fat-suppression prepulse, and an inversion recovery (IR) pulse.

For example, if the center frequency at which a hydrogen atom of an adipose tissue causes magnetic resonance is shifted during scanning, a fat-suppression prepulse does not effectively function in some cases. In step ST108, even when the center frequency is shifted during scanning, not only the fat-suppression prepulse but also the excitation pulse for collecting MR signals is corrected. Accordingly, the MR image with excellent image quality in which the fat-suppression prepulse effectively functions can be acquired.

In step ST109, the scanning function F2 determines whether to complete the second sequence. If the second sequence is not to be completed (NO in step ST109), the processing returns to step ST105. If the second sequence is to be completed (YES in step ST109), the processing ends. After completion of the second sequence, the image generation function F6 generates an MR image based on the MR signals collected during execution of scanning by the second sequence.

The shift amount of the center frequency may be corrected during execution of scanning by the second sequence, or may be corrected after execution of scanning by the second sequence. The image generation function F6 may perform a correction for minimizing effects of the shift amount on data based on MR signals obtained by the second sequence in the k-space based on the value CFcorr corresponding to the shift amount of the center frequency of the second sequence. For example, a zero-order phase or a first-order phase due to a shift of the center frequency caused in data on MR signals obtained by the second sequence may be corrected in the k-space. Further, the image generation function F6 may perform the correction for minimizing effects of the shift amount on data based on MR signals obtained by the second sequence in a real space based on the value CFcorr corresponding to the shift amount of the center frequency of the second sequence. For example, a positional deviation of the subject P occurring in data on the MR image generated from the MR signals may be corrected in the real space.

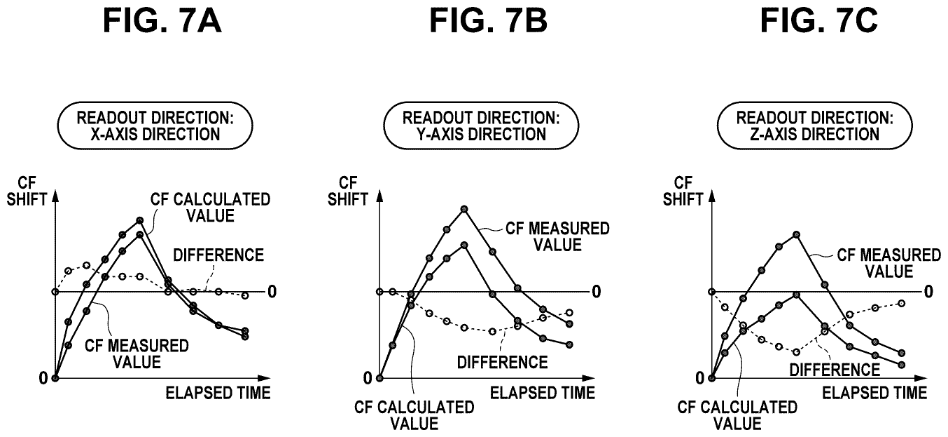

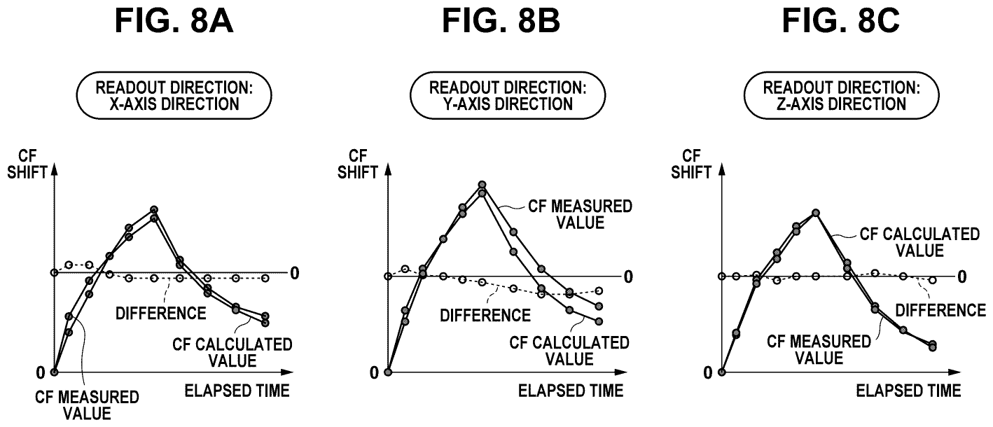

FIGS. 7A to 7C each illustrate an example of a temporal change of each of an actually measured shift amount (i.e., a center frequency (CF) measured value) of the center frequency during a main scan and a calculated shift amount (i.e., a CF calculated value) of the center frequency during the main scan that is calculated based on a relationship between the shift amount of the CF and the variation amount of the temperature of the gradient coil unit 11 during a prescan by the method according to the comparative example. FIGS. 8A to 8C each illustrate an example of a temporal change of each of an actually measured shift amount (i.e., the CF measured value) of the center frequency during the main scan and a calculated shift amount (i.e., the CF calculated value) of the center frequency during the main scan that is calculated based on a relationship between the shift amount of the CF and the variation amount of the temperature of the gradient coil unit 11 during the prescan by the method according to the exemplary embodiment. In FIGS. 7A to 8C, the term “difference” refers to a difference between the CF calculated value and the CF measured value. At a start of the main scan, the shift amount is “0”. In FIGS. 7A and 8A, the readout gradient magnetic field Gr during the main scan is applied by the gradient coil 11X corresponding to the X-axis. In FIGS. 7B and 8B, the readout gradient magnetic field Gr during the main scan is applied by the gradient coil 11Y corresponding to the Y-axis. In FIGS. 7C and 8C, the readout gradient magnetic field Gr during the main scan is applied by the gradient coil 11Z corresponding to the Z-axis.

In the comparative example, if the gradient coil to which the readout gradient magnetic field Gr is applied during the main scan is different from the gradient coil 11X to which the readout gradient magnetic field Gr is applied during the prescan (e.g., FIGS. 7B and 7C), an error between the CF calculated value and the CF measured value tends to be larger than that when the gradient coil to which the readout gradient magnetic field Gr is applied during the main scan is the same as the gradient coil 11X to which the readout gradient magnetic field Gr is applied during the prescan (e.g., FIG. 7A).

In the comparative example, the sequence executed in the prescan is not the same as the sequence executed in the main scan. Accordingly, even when the gradient coil 11X to which the readout gradient magnetic field is applied during the prescan is the same as the gradient coil 11X to which the readout gradient magnetic field is applied during the main scan (e.g., FIG. 7A), an error occurs between the CF calculated value and the CF measured value.

On the other hand, in the exemplary embodiment, a variation amount of the temperature of the gradient coil unit 11 and a shift amount of the center frequency are measured based the three settings, including the setting in which the readout gradient magnetic field Gr is applied by the gradient coil 11X corresponding to the X-axis, the setting in which the readout gradient magnetic field Gr is applied by the gradient coil 11Y corresponding to the Y-axis, and the setting in which the readout gradient magnetic field Gr is applied by the gradient coil 11Z corresponding to the Z-axis, during the prescan. Accordingly, as illustrated in FIGS. 8A to 8C, an error is less likely to occur between the CF calculated value and the CF measured value as compared with the comparative example even when the readout gradient magnetic field Gr is applied in any one of the axial directions of the gradient coil 11X corresponding to the X-axis, the gradient coil 11Y corresponding to the Y-axis, and the gradient coil 11Z corresponding to the Z-axis, during the main scan. Further, in the exemplary embodiment, the shift amount of the center frequency can be accurately corrected also on an oblique section (e.g., in a case where the readout gradient magnetic field Gr is divided in a plurality of axial directions).

Furthermore, in the exemplary embodiment, the first sequence is identical or similar to the second sequence. Accordingly, as illustrated in FIG. 8A, an error that occurs between the CF calculated value and the CF measured value when the gradient coil 11X to which the readout gradient magnetic field Gr is applied during the prescan is the same as the gradient coil 11X to which the readout gradient magnetic field Gr is applied during the main scan is smaller than that in the comparative example. The term “identical” used herein refers to a case where the type of pulse sequence and imaging conditions in the first sequence match the type of pulse sequence and imaging conditions in the second sequence. In this case, energy to be consumed by each of the gradient coil 11X corresponding to the X-axis, the gradient coil 11Y corresponding to the Y-axis, and the gradient coil 11Z corresponding to the Z-axis in the first sequence matches energy to be consumed by each of the gradient coil 11X corresponding to the X-axis, the gradient coil 11Y corresponding to the Y-axis, and the gradient coil 11Z corresponding to the Z-axis in the second sequence.

The term “similar” used herein refers to a case where the type of pulse sequence or a part of imaging conditions of the first sequence matches the type of pulse sequence or a part of imaging conditions of the second sequence. In this case, the similarity increases as a degree of matching between the imaging conditions that affect the variation amount of the temperature of the gradient coil unit 11 increases.

For example, the ratio between energy to be consumed by the gradient coil 11X corresponding to the X-axis, the gradient coil 11Y corresponding to the Y-axis, and the gradient coil 11Z corresponding to the Z-axis upon execution of the first sequence and energy to be consumed by each of the gradient coil 11X corresponding to the X-axis, the gradient coil 11Y corresponding to the Y-axis, and the gradient coil 11Z corresponding to the Z-axis, and the ratio between the energy Egt to be consumed by the gradient coil 11X corresponding to the X-axis, the gradient coil 11Y corresponding to the Y-axis, and the gradient coil 11Z corresponding to the Z-axis upon execution of the second sequence and the energies Egx, Egy, and Egz to be consumed by the gradient coil 11X corresponding to the X-axis, the gradient coil 11Y corresponding to the Y-axis, and the gradient coil 11Z corresponding to the Z-axis, respectively, may be nearly equal on at least one of the X-axis, the Y-axis, and the Z-axis.

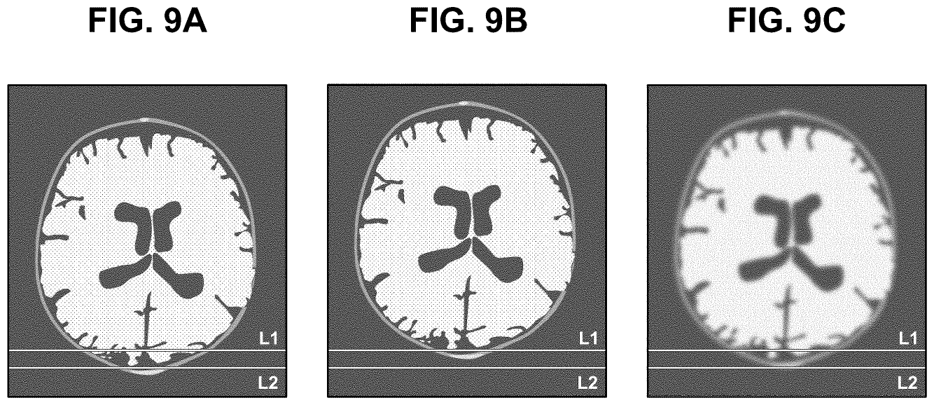

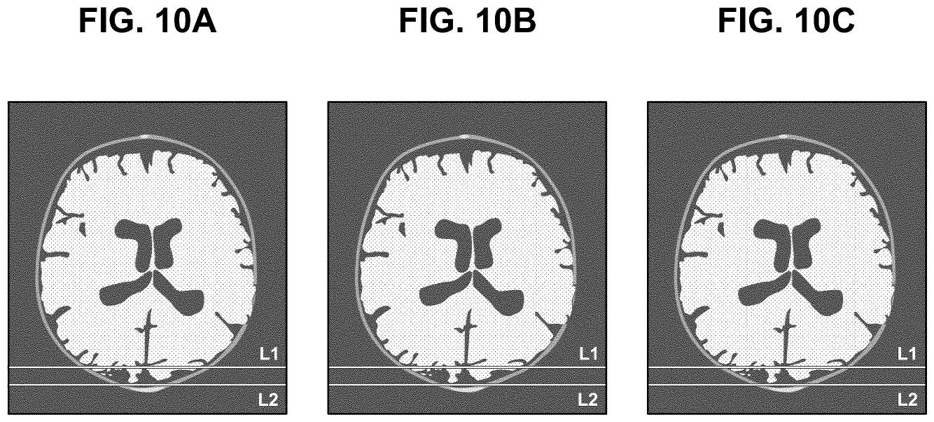

FIGS. 9A to 10C are diagrams each illustrating image quality of a signal-averaged MR image according to the comparative example or the exemplary embodiment. FIGS. 9A and 10A schematically illustrate MR images each obtained by the main scan corresponding to an addition count of one, FIGS. 9B and 10B schematically illustrate MR images each obtained by the main scan corresponding to the addition count of five, and FIGS. 9C and 10C schematically illustrate MR images each obtained by signal averaging MR images obtained by the main scan corresponding to the addition counts of one to five.

In the comparative example, as illustrated in FIGS. 9A and 9B, a positional deviation (see lines L1 and L2) has occurred due to a shift of the center frequency between the main scan corresponding to the addition count of one and the main scan corresponding to the addition count of five. Further, as illustrated in FIG. 9C, signal averaging of the images in which the positional deviation has occurred as illustrated in FIGS. 9A and 9B causes degradation of image quality such as a positional deviation or blur in the MR image.

On the other hand, in the exemplary embodiment, the shift of the center frequency during the main scan can be accurately corrected. Therefore, as illustrated in FIGS. 10A and 10B, a positional deviation is less likely to occur between the main scan corresponding to the addition count of one and the main scan corresponding to the addition count of five. Consequently, as illustrated in FIG. 10C, image degradation such as a positional deviation or blur is less likely to occur in the signal-averaged MR image.

The method in MRI and the MRI apparatus according to at least one of the exemplary embodiments described above can accurately correct the center frequency which can be changed during scanning and at which nuclear spin of a subject causes magnetic resonance.

In the exemplary embodiments described above, the term “processor” indicates circuitry such as a dedicated or general-purpose CPU, a Graphics Processing Unit (GPU), an ASIC, or a programmable logic device (e.g., a Simple Programmable Logic Device (SPLD), a Complex Programmable Logic Device (CPLD), and an FPGA).

In a case where the processor is, for example, a CPU, the processor reads out programs stored in the storage circuitry 41 and executes the programs to thereby implement various functions. In a case where the processor is, for example, an ASIC, the functions corresponding to the programs are directly built in as logic circuitry within the circuitry of the processor, instead of storing the programs in the storage circuitry 41. In this case, the processor implements various functions by hardware processing of reading out the programs built in the circuitry and executing the programs. Alternatively, the processor may implement various functions using a combination of software processing and hardware processing.

While the above-described exemplary embodiments illustrate an example where a single processor in processing circuitry implements the functions, the processing circuitry may include a combination of independent processors, and each processor may implement each function. In a case where a plurality of processors is provided, storage circuitry storing programs may be individually provided for each processor, or single storage circuitry may collectively store programs corresponding to all of processor functions.

The setting function F1, the scanning function F2, the acquisition function F3, the calculation function F4, the correction function F5, and the image generation function F6 described in the exemplary embodiments are examples of a setting unit, a scanning unit, an acquisition unit, a calculation unit, a correction unit, and an image generation unit, respectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method in a magnetic resonance imaging, the method comprising:
acquiring a first temperature variation amount as a variation amount of a temperature of a gradient coil unit which includes a gradient coil corresponding to an X-axis; a gradient coil corresponding to a Y-axis; and a gradient coil corresponding to a Z-axis; and a first frequency variation amount as a shift amount of a center frequency at which nuclear spin of a subject causes magnetic resonance, the first temperature variation amount and the first frequency variation amount being caused by execution of a first sequence based on a first setting in which a readout gradient magnetic field is applied in a direction of the X-axis by the gradient coil unit;
acquiring a second temperature variation amount as the variation amount of the temperature of the gradient coil unit and a second frequency variation amount as the shift amount of the center frequency, the second temperature variation amount and the second frequency variation amount being caused by execution of the first sequence based on a second setting in which the readout gradient magnetic field is applied in a direction of the Y-axis by the gradient coil unit;
acquiring a third temperature variation amount as the variation amount of the temperature of the gradient coil unit and a third frequency variation amount as the shift amount of the center frequency, the third temperature variation amount and the third frequency variation amount being caused by execution of the first sequence based on a third setting in which the readout gradient magnetic field is applied in a direction of the Z-axis by the gradient coil unit;
acquiring a fourth temperature variation amount as the variation amount of the temperature of the gradient coil unit caused by execution of a second sequence to be executed after the first sequence; and
calculating a value corresponding to the shift amount of the center frequency in the second sequence, based on the first temperature variation amount, the first frequency variation amount, the second temperature variation amount, the second frequency variation amount, the third temperature variation amount, the third frequency variation amount, the fourth temperature variation amount and a weighting value corresponding to a gradient magnetic field to be applied in the second sequence.

2. The method according to claim 1, further comprising setting a center frequency of a radio frequency (RF) pulse in the second sequence based on the calculated value corresponding to the shift amount of the center frequency in the second sequence, the RF pulse being applied to a subject to be imaged.

3. The method according to claim 2, wherein the center frequency of the RF pulse in the second sequence is set at least one of timings of between addition counts, between multi-slices and between dynamic scans during execution of the second sequence.

4. The method according to claim 1, further comprising correcting data corresponding to a magnetic resonance signal in a k-space obtained by the second sequence so that an effect of the shift amount is reduced based on the calculated value corresponding to the shift amount of the center frequency in the second sequence.

5. The method according to claim 1, further comprising correcting data corresponding to a magnetic resonance signal in a real space obtained by the second sequence so that an effect of the shift amount is reduced based on the calculated value corresponding to the shift amount of the center frequency in the second sequence.

6. The method according to claim 1, further comprising setting a center frequency of an RF pulse in the second sequence based on a value obtained by weighting a ratio between the first frequency variation amount and the first temperature variation amount, a ratio between the second frequency variation amount and the second temperature variation amount and a ratio between the third frequency variation amount and the third temperature variation amount by the weighting value, the RF pulse being applied to a subject to be imaged.

7. The method according to claim 1, wherein the weighting value includes a first value, a second value and a third value, the first value being a ratio between energy to be consumed by the gradient coil corresponding to the X-axis, the gradient coil corresponding to the Y-axis and the gradient coil corresponding to the Z-axis by executing the second sequence and energy to be consumed by the gradient coil corresponding to the X-axis by executing the second sequence, the second value being a ratio between energy to be consumed by the gradient coil corresponding to the X-axis, the gradient coil corresponding to the Y-axis and the gradient coil corresponding to the Z-axis by executing the second sequence and energy to be consumed by the gradient coil corresponding to the Y-axis by executing the second sequence, the third value being a ratio between energy to be consumed by the gradient coil corresponding to the X-axis, the gradient coil corresponding to the Y-axis and the gradient coil corresponding to the Z-axis by executing the second sequence and energy to be consumed by the gradient coil corresponding to the Z-axis by executing the second sequence.

8. The method according to claim 1,
Wherein each of the first temperature variation amount, the second temperature variation amount, the third temperature variation amount, and the fourth temperature variation amount are acquired at a plurality of predetermined positions on the gradient coil unit, and
wherein the value corresponding to the shift amount of the center frequency in the second sequence is calculated based on a plurality of first temperature variation amounts, the first frequency variation amount, a plurality of second temperature variation amounts, the second frequency variation amount, a plurality of third temperature variation amounts, the third frequency variation amount, a plurality of fourth temperature variation amounts and the weighting value corresponding to the gradient magnetic field to be applied in the second sequence.

9. The method according to claim 1, wherein the first sequence is identical or similar to the second sequence.

10. A method in a magnetic resonance imaging, the method comprising:
acquiring a first temperature variation amount as a variation amount of a temperature of a gradient coil unit which includes a gradient coil corresponding to a first axis and a gradient coil corresponding to a second axis, and acquiring a first frequency variation amount as a shift amount of a center frequency at which nuclear spin of a subject causes magnetic resonance, the first temperature variation amount and the first frequency variation amount being caused by execution of a first sequence based on a first setting in which a readout gradient magnetic field is applied in a direction of the first axis by the gradient coil unit;
acquiring a second temperature variation amount as the variation amount of the temperature of the gradient coil unit and a second frequency variation amount as the shift amount of the center frequency, the second temperature variation amount and the second frequency variation amount being caused by execution of the first sequence based on a second setting in which the readout gradient magnetic field is applied in a direction of the second axis by the gradient coil unit;
acquiring a third temperature variation amount as the variation amount of the temperature of the gradient coil unit caused by execution of a second sequence to be executed after the first sequence; and
calculating a value corresponding to the shift amount of the center frequency in the second sequence, based on the first temperature variation amount, the first frequency variation amount, the second temperature variation amount, the second frequency variation amount, the third temperature variation amount and a weighting value corresponding to a gradient magnetic field to be applied in the second sequence.

11. A magnetic resonance imaging apparatus comprising:
a static field magnet configured to generate a static magnetic field within a bore in which a subject to be imaged is located;
a gradient coil unit including a gradient coil corresponding to an X-axis, a gradient coil corresponding to a Y-axis, and a gradient coil corresponding to a Z-axis; and
a processing circuitry configured to:
acquire a first temperature variation amount as a variation amount of the temperature of the gradient coil unit and a first frequency variation amount as a shift amount of a center frequency at which nuclear spin of the subject causes magnetic resonance, the first temperature variation amount and the first frequency variation amount being caused by execution of a first sequence based on a first setting in which a readout gradient magnetic field is applied in a direction of the X-axis by the gradient coil unit;
acquire a second temperature variation amount as the variation amount of the temperature of the gradient coil unit and a second frequency variation amount as the shift amount of the center frequency, the second temperature variation amount and the second frequency variation amount being caused by execution of the first sequence based on a second setting in which the readout gradient magnetic field is applied in a direction of the Y-axis by the gradient coil unit;
acquire a third temperature variation amount as the variation amount of the temperature of the gradient coil unit and a third frequency variation amount as the shift amount of the center frequency, the third temperature variation amount and the third frequency variation amount being caused by execution of the first sequence based on a third setting in which the readout gradient magnetic field is applied in a direction of the Z-axis by the gradient coil unit;
acquire a fourth temperature variation amount as the variation amount of the temperature of the gradient coil unit caused by execution of a second sequence to be executed after the first sequence; and
calculate a value corresponding to the shift amount of the center frequency in the second sequence, based on the first temperature variation amount, the first frequency variation amount, the second temperature variation amount, the second frequency variation amount, the third temperature variation amount, the third frequency variation amount, the fourth temperature variation amount and a weighting value corresponding to a gradient magnetic field to be applied in the second sequence.

12. The magnetic resonance imaging apparatus according to claim 11, wherein the processing circuitry is configured to set a center frequency of an RF pulse in the second sequence based on the value corresponding to the shift amount of the center frequency in the second sequence, the RF pulse being applied to the subject.

13. The magnetic resonance imaging apparatus according to claim 12, wherein the processing circuitry is configured to set the center frequency of the RF pulse in the second sequence at at least one of timings of between addition counts, between multi-slices, and between dynamic scans during execution of the second sequence.

14. The magnetic resonance imaging apparatus according to claim 11, wherein the processing circuitry is configured to correct data corresponding to a magnetic resonance signal in a k-space obtained by the second sequence so that an effect of the shift amount is reduced based on the value corresponding to the shift amount of the center frequency in the second sequence.

15. The magnetic resonance imaging apparatus according to claim 11, wherein the processing circuitry is configured to correct data corresponding to a magnetic resonance signal in a real space obtained by the second sequence so that an effect of the shift amount is reduced based on the value corresponding to the shift amount of the center frequency in the second sequence.

16. The magnetic resonance imaging apparatus according to claim 11, wherein the processing circuitry is configured to set a center frequency of an RF pulse in the second sequence based on a value obtained by weighting a ratio between the first frequency variation amount and the first temperature variation amount, a ratio between the second frequency variation amount and the second temperature variation amount and a ratio between the third frequency variation amount and the third temperature variation amount by the weighting value, the RF pulse being applied to a subject to be imaged.

17. The magnetic resonance imaging apparatus according to claim 11, wherein the weighting value includes a first value, a second value and a third value, the first value being a ratio between energy to be consumed by the gradient coil corresponding to the X-axis, the gradient coil corresponding to the Y-axis and the gradient coil corresponding to the Z-axis by executing the second sequence and energy to be consumed by the gradient coil corresponding to the X-axis by executing the second sequence, the second value being a ratio between energy to be consumed by the gradient coil corresponding to the X-axis, the gradient coil corresponding to the Y-axis and the gradient coil corresponding to the Z-axis by executing the second sequence and energy to be consumed by the gradient coil corresponding to the Y-axis by executing the second sequence, the third value being a ratio between energy to be consumed by the gradient coil corresponding to the X-axis, the gradient coil corresponding to the Y-axis and the gradient coil corresponding to the Z-axis by executing the second sequence and energy to be consumed by the gradient coil corresponding to the Z-axis by executing the second sequence.
